(19) United States
(12) Patent Application Publication
(10) Pub. No.: US 2012/0050959 A1
(43) Pub. Date: Mar. 1, 2012

(54) Under counter utility board

(76) Inventor: David Whitehead, Wesley Chapel, FL (US)

(21) Appl. No.: 12/870,826

(22) Filed: Aug. 29, 2010

(51) Int. Cl. H05K 7/00

(52) U.S. Cl. 361/679.01

(57) ABSTRACT

A display device to display information may include a first panel adapted to be detachably connected to a bottom surface of a kitchen cabinet and a second panel being pivotably connected to the first panel. The second panel may be detachably connected to the first panel. The first panel may include a first detachable fastening device and the second panel may include a second detachable fastening device. The first detachable fastening device may include a magnet, and the second detachable fastening device may include a magnet.

### FIELD OF THE INVENTION

The invention relates to a display device, more particularly to a display device with a foldable panel.

### BACKGROUND

The kitchen is a hub of most homes because it may be the one place where the entire family meets for meals. Furthermore, due to the preparation time of these meals, the meal preparer spends a great deal of time in the kitchen. The younger family members may congregate in the kitchen because the meal preparer may be found there. In any household, there is a need to communicate information to other household members or simply to jot down notes in order that these notes may be preserved for use at a later time.

Typically, the wall surface of the kitchen is fairly well covered with kitchen cabinets which may store various food items and china that will be used in the food preparation process and the presentation of the food to the various family members. Having sufficient work surfaces at approximately waist level is also an important feature for the modern kitchen. The need for the work surface is tends to divide the kitchen cabinets into upper kitchen cabinets which may be positioned above the work surface, and lower kitchen cabinets having a upper surface which may support the work surface. The work surface is generally in a spaced relationship with the upper kitchen cabinets to define a space sufficient to allow the meal preparer sufficient space to work with various kitchen utensils such as mixers, toasters and the like.

### SUMMARY

A display device to display information may include a first panel adapted to be detachably connected to a bottom surface of a kitchen cabinet and a second panel being pivotably connected to the first panel.

The second panel may be detachably connected to the first panel.

A display device to display information may include a first panel adapted to be detachably connected to a bottom surface of a kitchen cabinet and a third panel being pivotably connected to the first panel;

The third panel may be detachably connected to the first panel, and the third panel may include a slot having an opening to access the slot.

The first panel may include a first detachable fastening device and the second panel may include a second detachable fastening device.

The first detachable fastening device may include a magnet, and the second detachable fastening device may include a magnet.

The first panel may be pivotably connected to the second panel with a hinge, and the hinge may be a piano hinge.

The third panel may include a portion having a cork surface, and the third panel may include a portion having a metal surface.

The third panel may include a portion having a whiteboard surface, and the third panel may include a portion having a transparent surface.

The third panel may include a portion with a mirror surface, and the third panel may include a portion having a magnifying surface, and the third panel may include a portion having a magnifying surface.

### BRIEF DESCRIPTION OF THE DRAWINGS

The invention may be understood by reference to the following description taken in conjunction with the accompanying drawings, in which, like reference numerals identify like elements, and in which:

FIG. 1 illustrates a perspective view of the display device of the present invention;

FIG. 2 illustrates a perspective view of the display device of the present invention;

FIG. 3 illustrates a front view of the third panel of the present invention;

FIG. 4 illustrates a back view of the third panel of the present invention;

FIG. 5 illustrates a side view of the third panel of the present invention;

FIG. 6 illustrates a top view of the third panel of the present invention;

FIG. 6a illustrates a bottom view of the third panel of the present invention;

FIG. 7 illustrates a perspective view of the display device and bottom surface of the kitchen cabinet;

FIG. 8 illustrates a perspective view of the display device of the present invention;

FIG. 9 illustrates a sectional view of the display device of the present invention;

FIG. 10 illustrates a system view including the display device of the present invention;

FIG. 11 illustrates the display device of the present invention being used in the kitchen;

FIG. 12 illustrates the display device being used in a kitchen;

FIG. 13 illustrates the display device being used as a magnifier;

FIG. 14 illustrates the display device being used as a calendar;

FIG. 15 illustrates the display device being used as a calendar.

FIG. 16 illustrates the display device including a first surface of cork

FIG. 17 illustrates the display device displaying a emergency list of phone numbers.

### DETAILED DESCRIPTION

The present invention advantageously uses the space defined by the lower surface of the upper kitchen cabinets and the work surface. The present invention provides a foldable display 100 which may be used for a multitude of purposes and may fold between a first position where a display surface is visible and extends from the bottom surface of the upper kitchen cabinets. The display surface extends a modest distance from the work surface in order to avoid interference with objects placed on the work surface. The foldable display may rotate to a second position where the display surface may be substantially flush with the bottom surface of the upper kitchen cabinets in order in order to provide a virtually invisible appearance when not being used by the users of the kitchen. The foldable display may be used in bathrooms or other rooms where there is a need for such a foldable display. The purpose of the foldable display is to keep needed items within easy reach yet allow for the storage of the foldable display under the bottom surface of the upper kitchen cabinet. The foldable display may retain such items such as calendars, schedules, receipts, lists, photos, emergency numbers, frequent contacts, temporary notes, and other such messages. The foldable display may include a first panel or first plate and a second panel or second plate which may be hinged together for example with a piano type hinge. The first panel 101 may be detachably connected to the bottom surface 103 of the kitchen cabinet by a first detachable fastening device 113 Velcro, double-sided tape, permanent or releasable glue, bolts, or screws or other such devices which may be positioned on the bottom surface 103 of the kitchen cabinet. The first detachable fastening device 113 which may be Velcro, double sided tape, permanent or releasable glue, bolts or screws or other such devices which may be positioned on the top surface 117 of the first panel 101 and may cooperate with a second detachable fastening device 115 to detachably connect to the bottom surface 103 of the kitchen cabinet. The leading edge of the bottom surface 105 of the second panel 107 may include a hinge device 119 which may be a piano type hinge to pivotably connect to the leading edge of the top surface 139 of the second panel 107. The first panel 101 may be detachably connected to the second panel 107 by a third fastening device 131 which may be Velcro, cooperating magnets or other such fastening devices so that the first panel 101 may be stowed adjacent to the second panel in a substantially parallel position in the second position and may be rotated substantially 90° where the second panel 101 is generally visible and usable by the user in the first position.

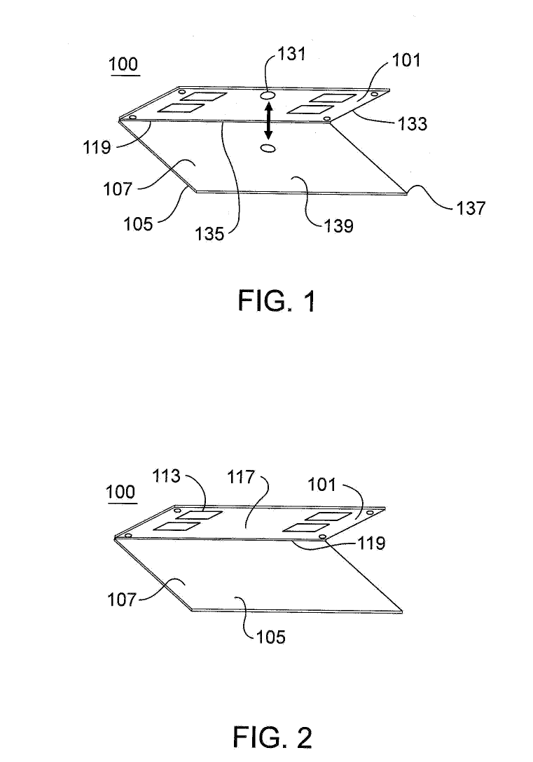

FIG. 1 illustrates the first panel 101 and the second panel 107 which may be substantially planar and may be rigid and maybe formed from plastic, metal, wood or other appropriate material.

FIG. 1 illustrates that the first panel 101 may include a top surface 117 in a spaced relationship with respect to a bottom surface 133 which may be connected to the top surface by a peripheral edge surface 135.

FIG. 1 additionally illustrates the second panel 107 which may include a top surface 139 which may be in a spaced relationship to the bottom surface 105 which may be connected to the top surface 139 by a peripheral edge surface 137.

FIG. 1 illustrates the third fastening device 131 which may be positioned on the bottom surface 103 of the kitchen cabinet or may be embedded within the first panel 101 and a cooperating third fastening device 131 which may be positioned on the top surface 139 or may be embedded within the second panel 107.

FIG. 2 illustrates the first panel 101 and the second panel 107 which may be pivotably connected together by the hinge device 119. FIG. 2 illustrates the first detachable fastening device 113 which may be segmented/distributed across the top surface 117 and the fastening device 113 may cooperate with a second detachable fastening device 115 (not shown) to detachably connect to the bottom surface 103 of the kitchen cabinet.

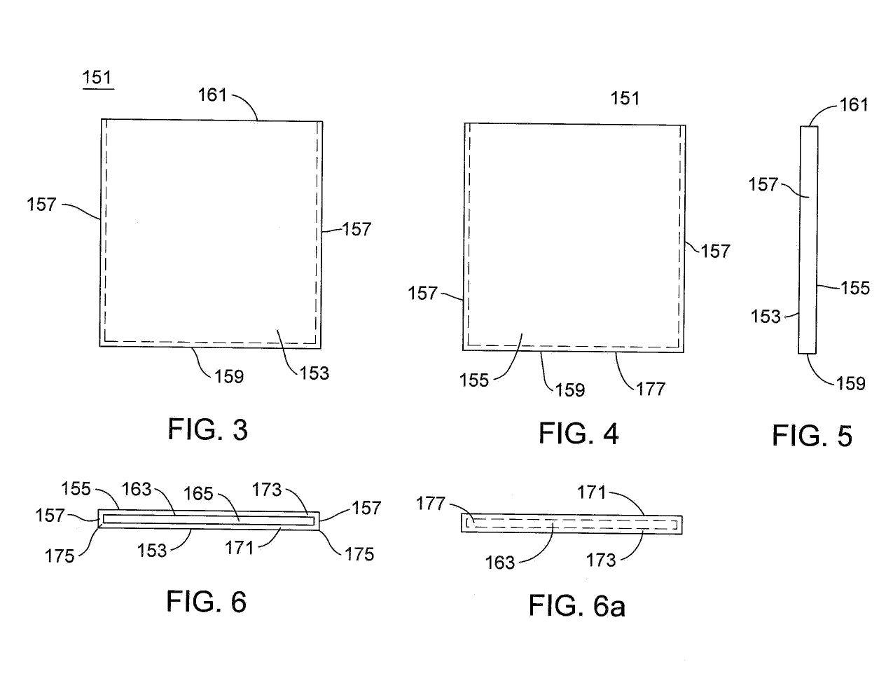

FIG. 3 illustrates a another embodiment of the second panel 107, more particularly FIG. 3 illustrates a third panel 151 which operates and is positioned the same way as the second panel 107 and which may include a front surface 153 which may be connected to a pair of opposing side surfaces 157 and may be connected to a bottom surface 159 and an opposing top surface 161 which may be in the form of a rectangle.

The third panel 151 is illustrated in FIG. 4 which illustrates the back surface 155 which may be positioned opposed to the front surface 153 and connected to a pair of opposing side surfaces 157 and may be connected to the bottom surface and 159 and to a top surface 161.

FIG. 5 illustrates the side surface 157 which may be connected to the front surface 153, the back surface 155 the bottom surface 159, and the top surface 161.

FIG. 6 illustrates a top view of the third panel 151 and the top surface 161 may be a rectangular shaped surface to define and opening 165 of a slot 163. The slot 163 extends into the third panel 151 to provide for papers, small books, calendars or other types of items. An example of these items may include schedules, recipes, lists, grocery, photos, emergency numbers, frequent contacts, temporary notes and other similar types of things.

The third panel 151 may be formed from a front wall 171 which may be opposed to a back wall 173 which may be connected to a pair of sidewalls 175 which may be connected to a bottom wall 177. The front wall 171 may be formed from plastic and may be transparent with no coloring (clear) or may be tinted with colors, maybe formed from cork in order to cooperate with push-pin attachment items, may be formed from metal to cooperate with magnets to attach items, may include a mirrored surface to cooperate with tape or post it attach items or may be a whiteboard (blackboard) in order to accommodate writing. The back wall 173 may be formed from plastic and may be transparent with no coloring or may be tinted with colors, may be opaque, may be plastic over wood, may be plastic over metal, may be metal for magnets.

FIG. 6a illustrates a bottom view of the third panel 151 and illustrates the bottom wall 177, the front wall 171 the back wall 173 and the side wall 175 and the slot 163.

FIGS. 3-6a describe a panel that has a slot for an item to be inserted. In my design, third panel 151 is one continuous piece that has been bent, so that 153 and 155 lay against each other providing a compression fit to hold in papers.

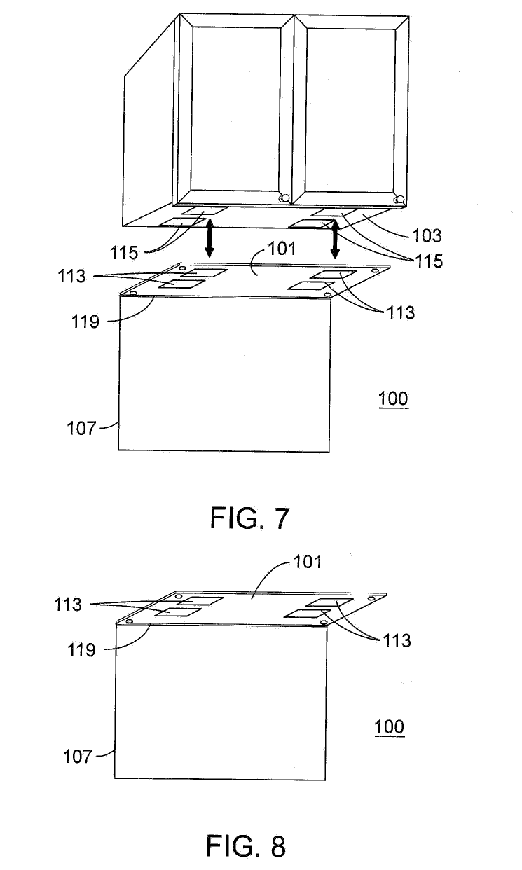

FIG. 7 illustrates the display device 100 which may include a first panel 101 which may be pivotably connected to the second panel 107 by the hinge device 119 and the first detachable fastening device 113 may cooperate with the second detachable fastening device 115 to detachably connect the first panel 101 to the bottom surface 103 of the kitchen cabinets.

FIG. 8 illustrates the display device 100, the first panel 101, the second panel 107 and the first detachable fastening device 113.

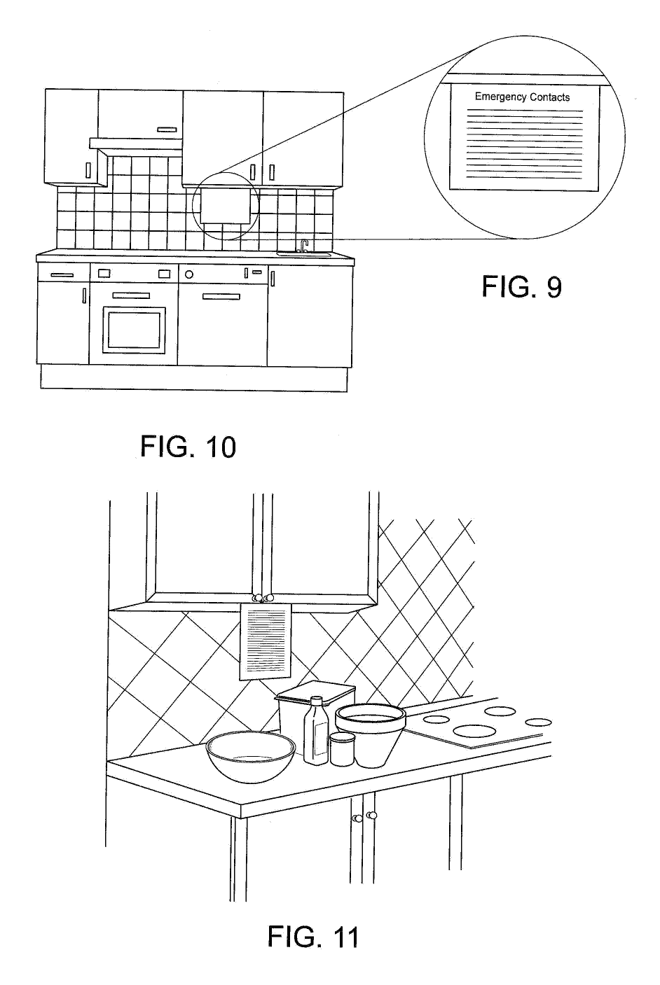

FIG. 10 illustrates the display device 100 positioned under the bottom surface 103 of the kitchen cabinets, and FIG. 9 illustrates a sectional view of the display device 100.

FIG. 11 illustrates that the display device 100 is displaying a menu.

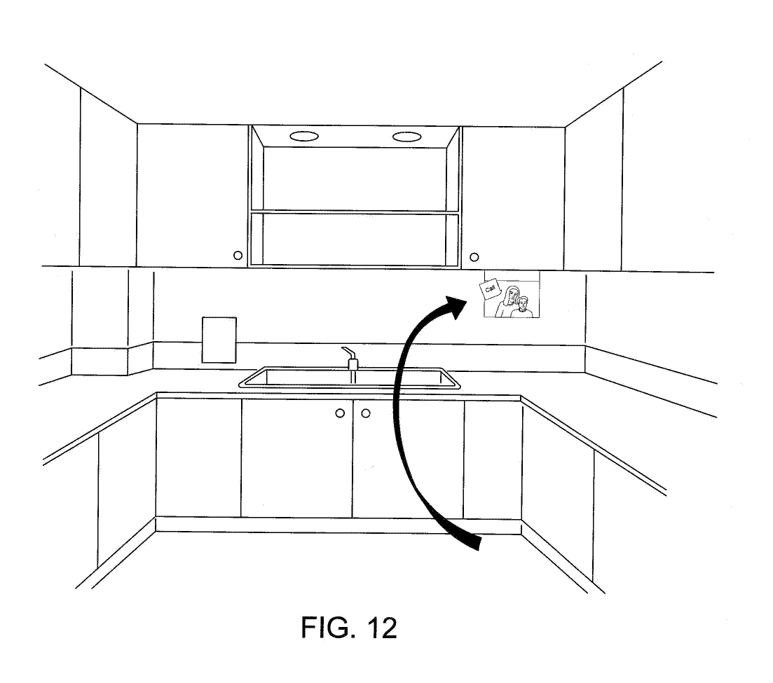

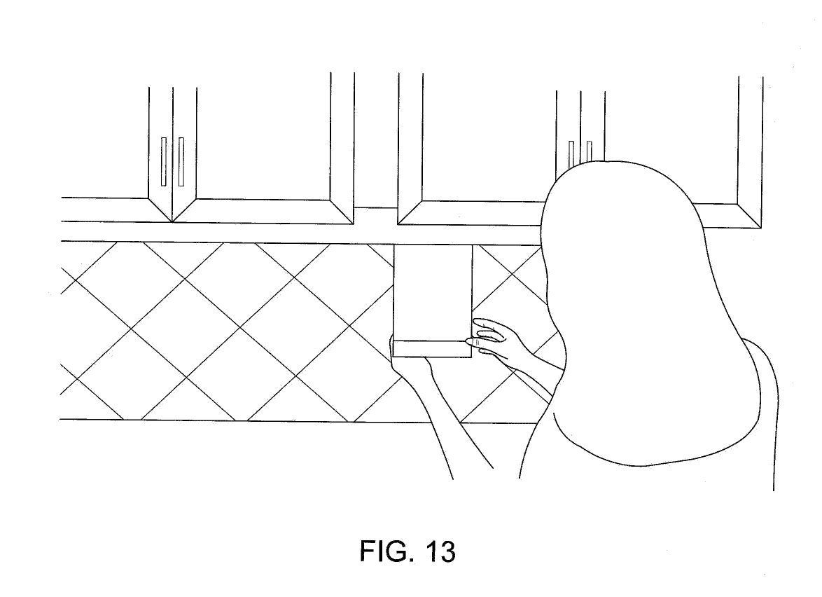

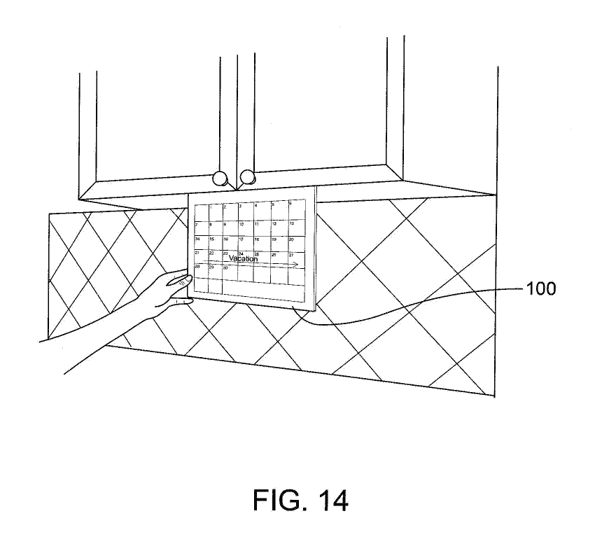

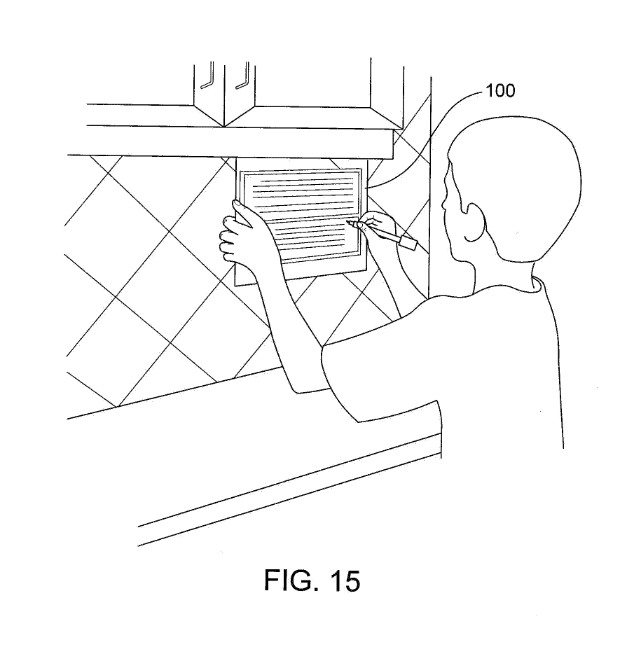

FIG. 12 illustrates that the display device 100 is displaying a photo.

FIG. 13 illustrates the display device being used as a magnifier.

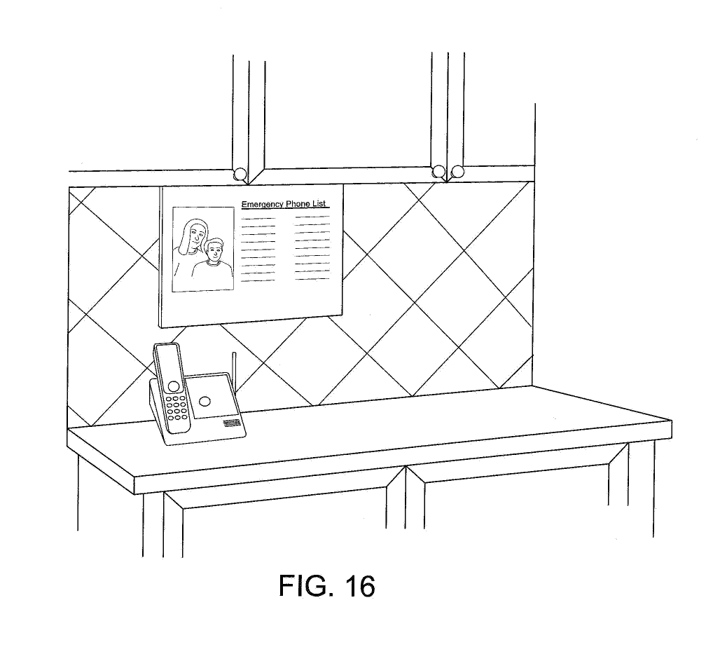

FIG. 14 illustrates the display device 100 displaying a calendar and the display device may accept notations on the front surface 153.

FIG. 15 illustrates the display device 100 being used by a user.

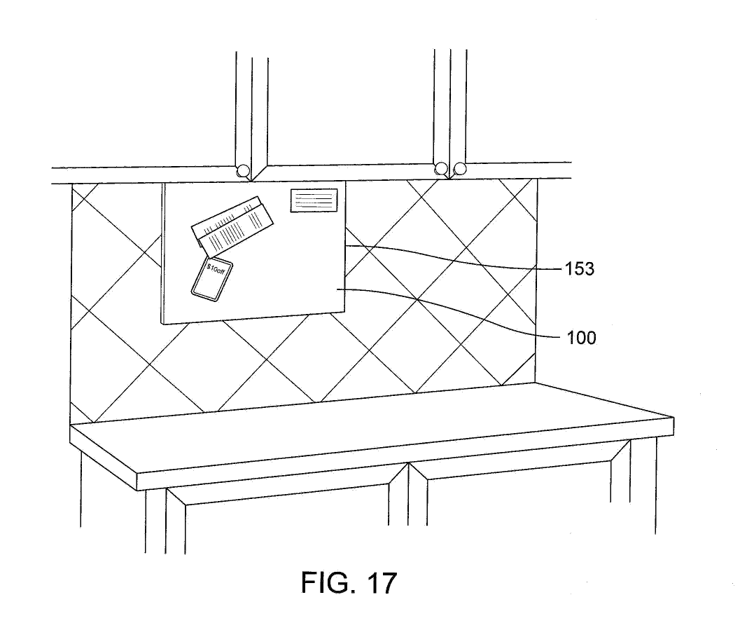

FIG. 16 illustrates the display device 100 including a first surface 153 of cork.

FIG. 17 illustrates the display device 100 displaying a emergency list of phone numbers.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1) A display device to display information, comprising:
a first panel adapted to be detachably connected to a bottom surface of a kitchen cabinet;
a second panel being pivotably connected to the first panel;
wherein the second panel is detachably connected to the first panel.

2) A display device to display information, comprising:
a first panel adapted to be detachably connected to a bottom surface of a kitchen cabinet;
a third panel being pivotably connected to the first panel;
wherein the third panel is detachably connected to the first panel;
wherein the third panel includes a slot having an opening to access the slot.

3) A display device to display information as in claim 1, wherein the first panel includes a first detachable fastening device and the second panel includes a second detachable fastening device.

4) A display device to display information as in claim 3, wherein the first detachable fastening device includes a magnet.

5) A display device to display information as in claim 3, wherein the second detachable fastening device includes a magnet.

6) A display device to display information as in claim 1, wherein the first panel is pivotably connected to the second panel with a hinge.

7) A display device to display information as in claim 6, wherein the hinge is a piano hinge.

8) A display device to display information as in claim 2, wherein the third panel includes a portion having a cork surface.

9) A display device to display information as in claim 2, wherein the third panel includes a portion having a metal surface.

10) A display device to display information as in claim 2, wherein the third panel includes a portion having a whiteboard surface.

11) A display device to display information as in claim 2, wherein the third panel includes a portion having a transparent surface.

12) A display device to display information as in claim 2, wherein the third panel includes a portion with a mirror surface.

13) A display device to display information as in claim 2, wherein the third panel includes a portion having a magnifier surface.
